(19) United States
(12) Patent Application Publication
(10) Pub. No.: US 2009/0020804 A1
(43) Pub. Date: Jan. 22, 2009

(54) SEMICONDUCTOR DEVICE AND METHOD FOR FABRICATING THE SAME

(75) Inventor: Yong Geun LEE, Eumseong-gun (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/176,104

(22) Filed: Jul. 18, 2008

(30) Foreign Application Priority Data
Jul. 19, 2007 (KR) 10-2007-0072161

(51) Int. Cl. H01L 29/00; H01L 23/58; H01L 21/31

(52) U.S. Cl. 257/324; 257/640; 438/761; 257/E29.001; 257/E23.001; 257/E21.24

(57) ABSTRACT

A semiconductor device and a method for fabricating the same. The semiconductor device includes a gate pattern formed on a semiconductor substrate, a first impurity-doped region formed in the substrate on one side of the gate pattern and a second impurity-doped region formed in the substrate on the other side of the gate pattern, a salicide shielding film pattern partially covering either the first impurity-doped region or the second impurity-doped region, an insulating film formed on the semiconductor substrate, the insulating film including a first hole which exposes the salicide shielding film pattern, and a second hole which partially exposes the first impurity-doped region or the second impurity-doped region that is not covered by the salicide shielding film pattern, and a first line coming in contact with the salicide shielding film pattern through the first hole.

This application claims the benefit of the Korean Patent Application No. 10-2007-0072161, filed on 19 Jul. 2007, which is hereby incorporated by reference as if fully set forth herein.

### BACKGROUND

1. Field of the Invention

Embodiments of the present invention relate to semiconductor devices. More specifically, embodiments of the present invention relate to semiconductor devices wherein the code design can be readily changed, and a method for fabricating the same.

2. Discussion of the Related Art

Embedded non-volatile memory devices are devices wherein non-volatile memory is integrated with a logic circuit capable of operating the memory in a single chip. Typically, embedded non-volatile memory devices are fabricated using basic logic fabrication techniques known in the art in conjunction with various techniques for fabricating non-volatile memory.

Various types of embedded non-volatile memories are known and may be selected for use depending on to the desired specifications of the end application. Similarly, various non-volatile memory designs are known in the art, and the specific design may vary, depending on the code stored in the memory.

The fabrication of semiconductor devices, including those used in non-volatile memories, uses a patterning process using a mask, wherein the width of the mask pattern may vary depending on the pattern of the semiconductor device being fabricated.

For example, when a gate pattern is being formed in the semiconductor device, the mask pattern comprises a complex pattern. Because of the complexity of the pattern, when the mask is improperly aligned or any shaking occurs during the fabrication process, the resulting semiconductor device may have defects or deteriorated reliability. In addition to the difficulties that arise during the fabrication process due to the complexity of the mask pattern, the costs associated with forming the mask pattern are expensive.

Any variation in the design of the non-volatile memory device results in a variation in the mask design. This requires a new mask pattern, which may result in added manufacturing expenses, deteriorated process reliability, and loss of time as the new design is produced and tested.

### SUMMARY

Accordingly, embodiments of the present invention are directed to semiconductor devices and methods for fabricating a semiconductor device that substantially obviates one or more problems, limitations, or disadvantages of the related art.

One example embodiment provides a semiconductor device whose design can be readily changed using an inexpensive mask.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

One example aspect of the invention is a semiconductor device comprising a gate pattern formed on a semiconductor substrate, a first impurity-doped region formed in the semiconductor substrate on one side of the gate pattern and a second impurity-doped region formed in the semiconductor substrate on the other side of the gate pattern, a salicide shielding film pattern which partially covers either the first impurity-doped region or the second impurity-doped region, an insulating film formed on the semiconductor substrate and salicide shielding film pattern, the insulating film including a first hole which exposes the salicide shielding film pattern and a second hole which partially exposes the first impurity-doped region or second impurity-doped region that is not covered by the salicide shielding film pattern, and a first line coming in contact with the salicide shielding film pattern through the first hole.

Another example embodiment is a method for fabricating a semiconductor device having a code-changed transistor comprising forming a gate pattern on a semiconductor substrate, forming a first impurity-doped region in the semiconductor substrate on one side of the gate pattern and forming a second impurity-doped region in the semiconductor substrate on the other side of the gate pattern, forming a salicide shielding film over the entire surface of the semiconductor substrate and gate pattern;, forming a photoresist pattern on the salicide shielding film, patterning the salicide shielding film using the photoresist pattern as a mask in order to form a salicide shielding film pattern, forming a metal layer on the semiconductor substrate and salicide shielding film pattern, annealing the metal layer and the salicide shielding film pattern in order form a salicide, removing the remaining metal layer after forming the salicide, forming an insulating film on the semiconductor substrate, patterning the insulating film to form a first hole and a second hole, and forming a first line coming in contact with the salicide shielding film pattern though the first hole to in order to change the transistor design.

It is to be understood that both the foregoing general description and the following detailed description of embodiments of the present invention are exemplary and explanatory and are intended to provide further explanation of the invention as claimed.

### BRIEF DESCRIPTION OF THE DRAWINGS

The accompanying drawings, which are included to provide a further understanding of the invention are incorporated in and constitute a part of this application. The drawings illustrate embodiment(s) of the invention and along with the description serve to explain the principle of the invention. In the drawings:

FIG. 1A is a circuit diagram of a semiconductor memory device;

FIG. 1B is a circuit diagram of a semiconductor memory device design which is modified from the circuit diagram of FIG. 1A according to one embodiment of the present invention;

FIG. 2 is a plan view illustrating a semiconductor device design which is modified according to one embodiment of the present invention;

FIG. 3 is a cross-sectional view taken along the line I-I′ of the FIG. 2; and

FIGS. 4-12 are cross-sectional views illustrating a process for fabricating a semiconductor device according to one embodiment of the present invention.

### DETAILED DESCRIPTION OF EXAMPLE EMBODIMENTS

Hereinafter, a semiconductor and a method for fabricating the same will be described in detail with reference to the accompanying drawings. In the following description, example embodiments of the invention are described in terms of a “first semiconductor member” and a “second semiconductor member.” Similar terms are used to specify other parts of the semiconductor, without limitation t. Accordingly, when referring to the “first semiconductor member,” “second semiconductor member” or the like, it is clearly understood that a semiconductor package comprises at least two or more members and, optionally, includes replaceable members.

For further understanding of examples of the present invention, the dimensions of different constitutional elements have been exaggerated and the scale shown in the drawings may be different from the actual dimensions of the elements. All of the elements illustrated in the drawings are not necessarily included in the present invention nor are they inclusive of all the elements that may be used in association with embodiments of the invention, and thus the elements may be added or deleted, depending on the specific configuration of the semiconductor.

With regard to description of preferred embodiments according to the present invention, it will be understood that, when a layer (film), a region, a pad, a pattern and/or a structure are referred to as being “on/above/over/upper (on top of)” or “down/below/under/lower (on bottom of)” another substrate, layer (film), region, pad and/or pattern, they can directly contact the other substrate, layer (film) region, pad or pattern, or have intervening layers (films), regions, pads, patterns or structures there between. Accordingly, this meaning should be understood in regard to technical concept of the present invention.

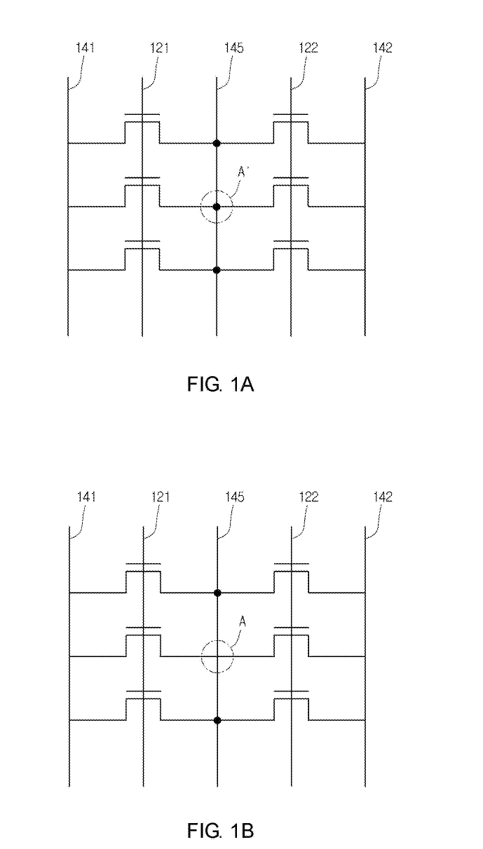

FIG. 1A is a circuit diagram of a semiconductor memory device. FIG. 1B is a circuit diagram of a semiconductor memory device that is modified from the circuit diagram of FIG. 1A according to one embodiment of the present invention.

As shown in FIGS. 1A and 1B, the semiconductor memory device includes drain lines 141 and 142, source lines 145, and gate lines 121 and 122.

The specific coding design of the semiconductor memory device may be changed. In the example shown in FIG. 1A, the source line 145 is electrically connected to a source region of a transistor in a region A′. Alternatively, as shown in FIG. 1B, the source line 145 may be not connected electrically to the source region of the transistor in the region A.

Embedded memories are often in the fabrication and design of semiconductors. Examples of embedded memories include SRAM, DRAM, FLASH, ROM, and the like. The ROM design may be altered, according to the specific codes of the semiconductor memory device.

As the region A′ is changed to the region A, in order to code the transistor to a high “1” level, the transistor provided in the corresponding cell must not operate even when in a saturation mode. For this purpose, the source lines 145 must not be electrically connected to a source region of the corresponding transistor.

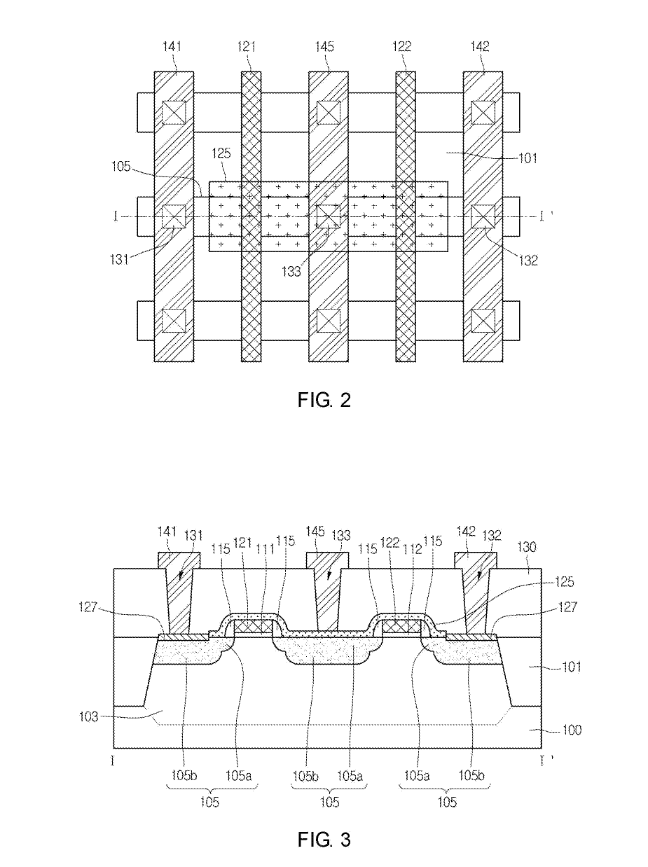

FIG. 2 is a plan view illustrating a semiconductor device design modified according to another embodiment of the present invention. FIG. 3 is a cross-sectional view taken along the line I-I′ of the FIG. 2.

As shown in FIGS. 2 and 3, a device isolation film pattern 101 is formed on a semiconductor substrate 100. The device isolation film pattern 101 defines an active area of the semiconductor device.

For example, the device isolation film pattern 101 may be a shallow trench isolation pattern.

A well region 103 is provided with the device isolation film pattern 101, by implanting an impurity in the semiconductor substrate 100. A first gate insulating film pattern 111 and a first gate pattern 121 are formed on the semiconductor substrate 100.

For example, the first gate insulating film pattern 111 may be a thermal oxide film pattern, and the first gate pattern 121 may be a polysilicon pattern.

A second gate insulating film pattern 112 is spaced apart from the first gate pattern 121 on the semiconductor substrate 100 by a predetermined distance and a second gate pattern 122 is formed on the second gate insulating film pattern 112.

For example, the second gate insulating film pattern 112 may be a thermal oxide film pattern, and the second gate pattern 122 may be a polysilicon pattern.

Gate spacers 115 are formed on the sides of the first gate insulating film pattern 111 and the first gate pattern 121, as well as on the sides of the second gate insulating film pattern 112 and the second gate pattern 122.

An impurity-doped region 105 is formed on the semiconductor substrate 100 in the area of the semiconductor substrate 100 below the sides of the first and second gate patterns 121 and 122.

A low-concentration impurity-doped region 105a is formed under the gate spacer 115, and a high-concentration impurity-doped region 105b comprising a source region and a drain region is formed on each side of the first and second gate patterns 121 and 122.

A salicide shielding film pattern 125 that covers the first gate pattern 121 and the second gate pattern 122 is formed on the impurity-doped semiconductor substrate 100. According to the present invention, the salicide shielding film pattern may include a silicon oxide film that covers at least one of a first impurity-doped region and a second impurity-doped region, along with a silicon nitride film formed on the silicon oxide film.

The code of the semiconductor may be changed by forming the salicide shielding film pattern 125 such that it partially covers the impurity region 105 according to the modified design scheme of the semiconductor memory device in one embodiment of the present invention.

The salicide shielding film pattern 125 enables salicide to be formed in only a desired region and prevents the salicide from being formed in any undesired regions. In the embodiment of the present invention, the salicide shielding film pattern 125 is formed in a region where the code design is to be changed.

A salicide 127 is formed in a region of the semiconductor memory device where the original code design is to be maintained.

An interlayer dielectric 130 is formed over the entire surface of the semiconductor substrate 100. The interlayer dielectric 130 is formed to have three holes 131, 132 and 133, which partially expose the impurity region 105. At this time, the first and second holes 131 and 132 expose the salicide 127, while the third hole 133 exposes the salicide shielding film pattern 125.

Drain lines 141 and 142 are formed on the interlayer dielectric 130 and are in contact with the salicide 127 through the first and second holes 131 and 132.

Source lines 145 are formed on the interlayer dielectric 130 and are in contact with the salicide shielding film pattern 125 through the third hole 133.

Since the source lines 145 cannot connect to the impurity region located under the source lines because of the salicide shielding film pattern 125, the code in the region may be changed from high (“1”) to low (“0”).

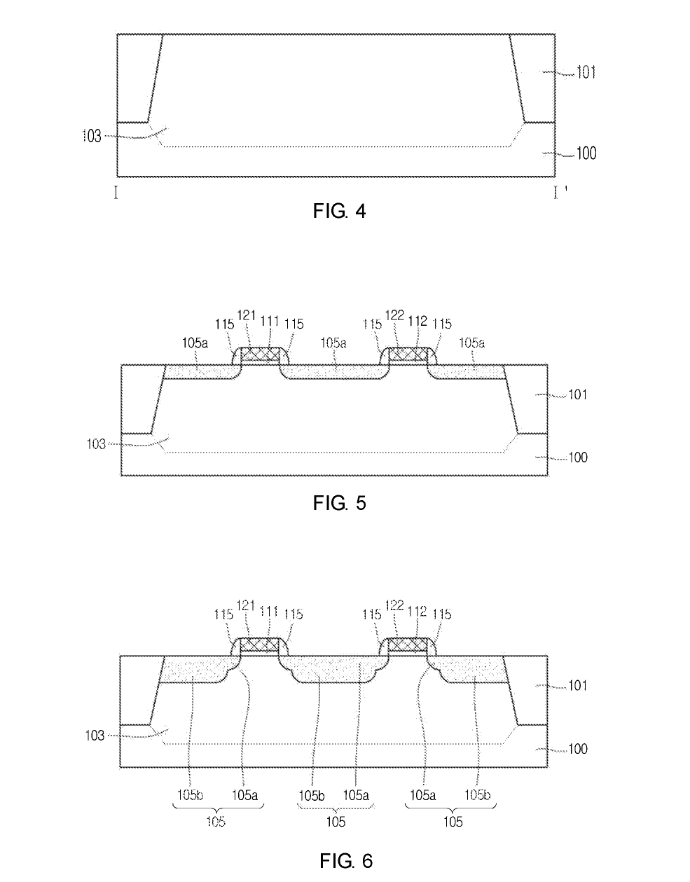

FIGS. 4-12 are cross-sectional views illustrating a process for fabricating a semiconductor device according to one embodiment of the present invention.

As shown in FIG. 4, a device isolation film pattern 101 is formed on the semiconductor substrate 100 in order to define an active area.

Then, an impurity is doped on the semiconductor substrate 100 to form a well region 103.

As shown in FIG. 5, the first gate insulating film pattern 111 and the first gate pattern 121 are formed on the semiconductor substrate 100.

For example, the first gate insulating film pattern 111 may be a thermal oxide film pattern, and the first gate pattern 121 may be a polysilicon pattern.

A second gate insulating film pattern 112 is formed on the semiconductor substrate 100 and a second gate pattern 122 is formed on the second gate insulating film pattern 112 such that the second gate insulating film pattern 112 and the second gate pattern 122 are spaced apart from the first gate pattern 121 by a predetermined distance. The first gate insulating film pattern 111 and the second gate insulating film pattern 112 may be formed at the same time. Similarly, the first gate pattern 121 and the second gate pattern 122 may be formed at the same time.

For example, the second gate insulating film pattern 112 may be a thermal oxide film pattern, and the second gate pattern 122 may be a polysilicon pattern.

Gate spacers 115 made of an insulator are formed on the sides of the first gate insulating film pattern 111 and the first gate pattern 121, and on the sides of the second gate insulating film pattern 112 and the second gate pattern 122.

A low-concentration impurity-doped region 105a is formed in the semiconductor substrate 100 under the gate spacers 155. A low-concentration impurity-doped region 105a may be formed by doping low-concentration impurity ions into the semiconductor substrate 100 using the first and second gate patterns 121 and 122 as masks.

As shown in FIG. 6, a high-concentration impurity is implanted at each side of the first and second gate patterns 121 and 122 in order to form a high-concentration impurity-doped region 105b constituting a source region or a drain region.

The low-concentration impurity-doped region 105a and the high-concentration impurity-doped region 105b are referred to as impurity-doped regions 105.

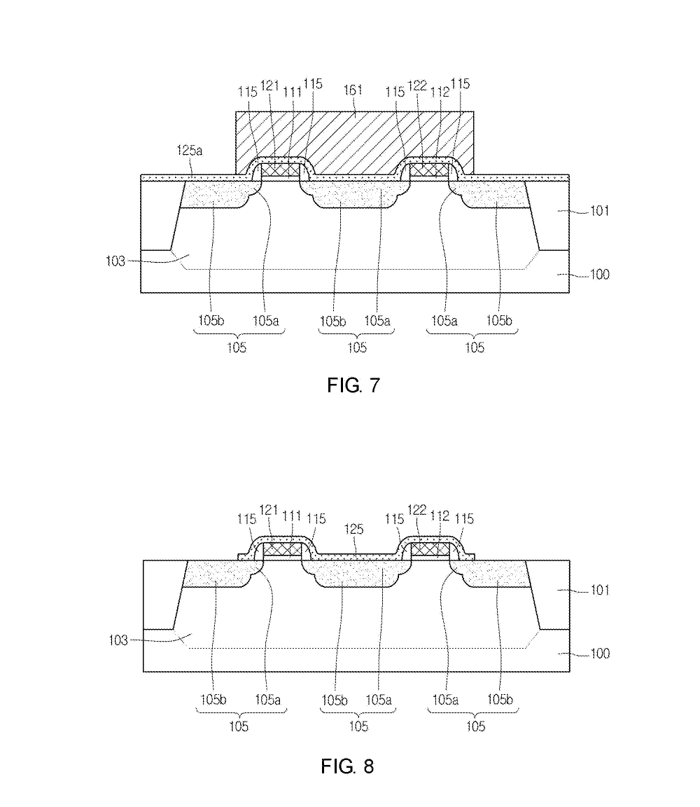

As shown in FIG. 7, a salicide shielding film 125a is formed on the semiconductor substrate 100.

For example, the salicide shielding film 125a may be a silicon oxide film.

For example, the salicide shielding film 125a may have a thickness between 200 and 600 Å.

For example, the salicide shielding film 125a may be a double layer comprising a silicon oxide film and a nitride oxide film formed over the silicon oxide film. More specifically, the salicide shielding film may be formed by forming a silicon oxide film on the semiconductor substrate and forming a silicon nitride film on the silicon oxide film.

The salicide shielding film 125a functions to prevent the salicide 127 from being formed in a predetermined region of the semiconductor substrate 100.

A photoresist pattern 161 is formed on the salicide shielding film 125a in a region where the code of the transistor is to be modified.

Masks used to form the photoresist pattern for forming the salicide shielding film pattern are inexpensive and exhibit superior resistance against process variations and pattern shifting during the manufacturing process, as compared to the complex masks used for forming active devices, gate patterns and contact holes. Furthermore, the photoresist pattern formation process is carried out after the active region has been defined, after the gate pattern and the contact holes have been formed in the semiconductor fabrication process, thus reducing the amount of design verification time. In addition, in the present invention, there is no need to further modify the additional mask processes, thus enabling the easy variation of the code design and minimizing the occurrences of defects during the code design variation process.

As shown in FIG. 8, the salicide shielding film 125a is patterned using the photoresist pattern 161 as a mask, in order to form a salicide shielding film pattern 125 in the region where the code is to be changed.

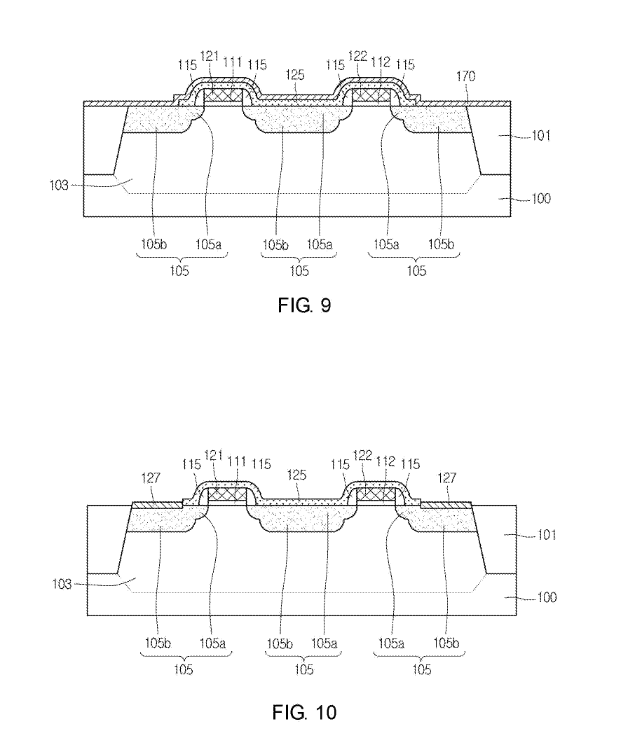

As shown in FIG. 9, a metal layer 170 is formed over the entire surface of the semiconductor substrate 100 provided with the salicide shielding film pattern 125.

For example, the metal layer 170 may comprise a metal layer for forming a salicide 127 and may be made of cobalt (Co).

Subsequently, the semiconductor substrate 100 is subjected to annealing process to cause the metal layer 170 to react with the semiconductor substrate 100 in order to form a salicide 127.

As shown in FIG. 10, the region of the metal layer 170 where the salicide 127 is not formed is removed from the semiconductor substrate 100.

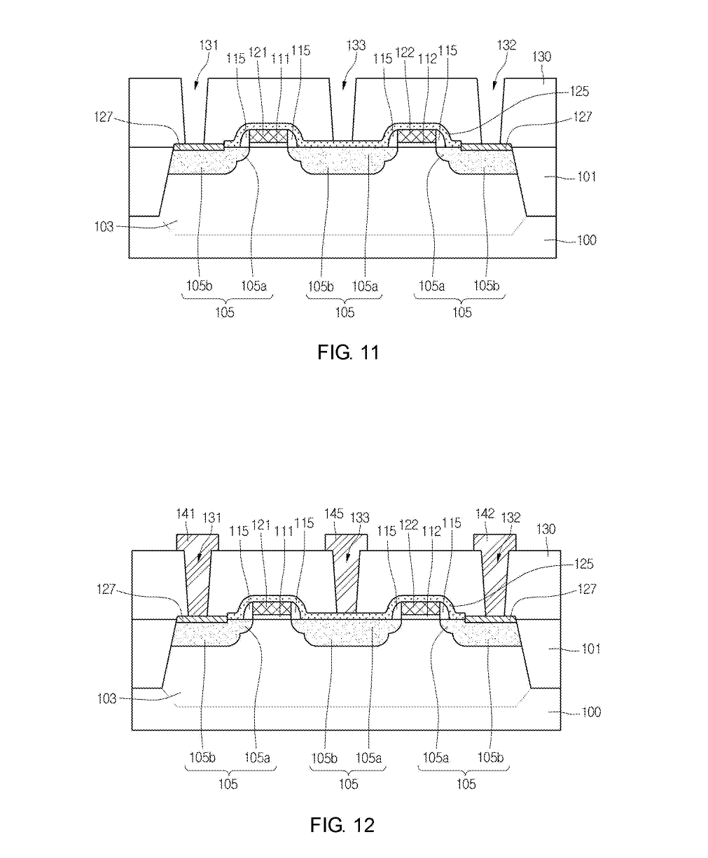

Subsequently, as shown in FIG. 11, an interlayer dielectric 130 is formed over the entire surface of the semiconductor substrate 100 including the salicide 127 and the salicide shielding film pattern 125.

The interlayer dielectric 130 is patterned to form a first hole 131 and a second hole 132 that partially expose the salicide 127 formed on the impurity-doped region 105, and a third hole 133 that exposes the salicide shielding film pattern 125.

Prior to patterning the interlayer dielectric 130, a polishing process may be performed to planarize the interlayer dielectric 130.

As shown in FIG. 12, drain lines 141 and 142 are formed on the interlayer dielectric 130 such that the drain lines come in contact with the salicide 127 through the first hole 131 and the second hole 132.

A via metal pattern may be formed inside the first to third holes 131, 132 and 133.

Since the third hole 133 is not electrically connected to the impurity-doped region 105 because of the salicide shielding film pattern 125, the code of the corresponding transistor may be changed from high to low.

One advantage of the semiconductor device and a method for fabricating the same is that the fabrication process margin and reliability can be improved by altering the design of the semiconductor device, and furthermore fabrication costs can be reduced and a design verification time can be shortened by designing an inexpensive mask for forming salicide to quickly and easily alter a design for forming a semiconductor device.

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A semiconductor device comprising:
a gate pattern formed on a semiconductor substrate;
a first impurity-doped region formed in the semiconductor substrate on one side of the gate pattern and a second impurity-doped region formed in the semiconductor substrate on the other side of the gate pattern;
a salicide shielding film pattern which partially covers either the first impurity-doped region or the second impurity-doped region;
an insulating film formed on the semiconductor substrate and salicide shielding film pattern, the insulating film including a first hole which exposes the salicide shielding film pattern and a second hole which partially exposes the first impurity-doped region or second impurity-doped region that is not partially covered by the salicide shielding film pattern; and
a first line coming in contact with the salicide shielding film pattern through the first hole.

2. The semiconductor device according to claim 1, wherein the salicide shielding film pattern has a thickness of between approximately 200 and 600 Å.

3. The semiconductor device according to claim 1, wherein the salicide shielding film pattern comprises at least one of a silicon oxide film and a silicon nitride film.

4. The semiconductor device according to claim 1, wherein the salicide shielding film pattern is used to change a code design of the first line.

5. The semiconductor device according to claim 1, further comprising:
a second line formed in the second hole, the second line connected to the first impurity-doped region or second impurity-doped region that is not partially covered by the salicide shielding film pattern.

6. The semiconductor device according to claim 3, wherein the salicide shielding film pattern comprises:
a silicon oxide film covering either the first impurity-doped region or the second impurity-doped region; and
a silicon nitride film formed on the silicon oxide film.

7. The semiconductor device according to claim 4, wherein the first line corresponds to a source line and the code is changed from high to low.

8. The semiconductor device according to claim 5, wherein the second line corresponds to a drain line.

9. A method for fabricating a semiconductor device having a code-changed transistor, comprising:
forming a gate pattern on a semiconductor substrate;
forming a first impurity-doped region in the semiconductor substrate on one side of the gate pattern and forming a second impurity-doped region in the semiconductor substrate on the other side of the gate pattern;
forming a salicide shielding film over the entire surface of the semiconductor substrate and gate pattern;
forming a photoresist pattern on the salicide shielding film in order to perform a code change;
patterning the salicide shielding film using the photoresist pattern as a mask in order to form a salicide shielding film pattern;
forming a metal layer on the semiconductor substrate and salicide shielding film pattern,
annealing the metal layer and salicide shielding film pattern in order to form a salicide;
removing the remaining metal layer after forming the salicide and forming an insulating film on the semiconductor substrate;
patterning the insulating film to form a first hole and a second hole; and
forming a first line which comes into contact with the salicide shielding film pattern though the first hole in order to change a transistor design.

10. The method according to claim 9, wherein the transistor is a non-volatile memory device.

11. The method according to claim 9, wherein the salicide shielding film comprises a silicon oxide film.

12. The method according to claim 9, wherein the code of the transistor is changed by altering the design of the mask used to form the salicide shielding film pattern.

13. The method according to claim 9, wherein the salicide shielding film pattern has a thickness of between about 200 and 600 Å.

14. The method according to claim 9, wherein the step of forming the salicide shielding film comprises:
forming a silicon oxide film on the semiconductor substrate; and
forming a silicon nitride film on the silicon oxide film.

15. The method according to claim 9, further comprising:
planarizing the insulating film prior to patterning the insulating film.

16. A transistor with a modified code, the transistor comprising:
a gate pattern formed on a substrate;
a first impurity-doped region formed in the substrate on one side of the gate pattern and a second impurity-doped region formed in the substrate on the other side of the gate pattern;
a salicide shielding film pattern which partially covers either the first impurity-doped region or the second impurity-doped region;
an insulating film formed on the substrate and salicide shielding film pattern, the insulating film including a first hole which exposes the salicide shielding film pattern and a second hole which partially exposes the first impurity-doped region or second impurity-doped region that is not partially covered by the salicide shielding film pattern;
a first line coming in contact with the salicide shielding film pattern through the first hole; and
a second line formed in the second hole, the second line connected to the first impurity-doped region or second impurity-doped region that is not partially covered by the salicide shielding film pattern.

17. The transistor according to claim 16, wherein the salicide shielding film pattern comprises:
a silicon oxide film covering either the first impurity-doped region or the second impurity-doped region; and
a silicon nitride film formed on the silicon oxide film.

18. The transistor according to claim 16, wherein the first line corresponds to a source line and the code of the transistor is changed from high to low.

19. The transistor according to claim 16, wherein the second line corresponds to a drain line.

20. The transistor according to claim 16, wherein the salicide shielding film pattern has a thickness of between about 200 and 600 Å.
